(19) United States
(12) Patent Application Publication
(10) Pub. No.: US 2014/0062839 A1
(43) Pub. Date: Mar. 6, 2014

(54) DUAL-FACE TRANSPARENT VIEWING SCREEN

(71) Applicant: Thales, Neuilly Sur Seine (FR)

(72) Inventors: Johanna DOMINICI, Eysines (FR); Sebastian Ellero, Francescas (FR); Laurent Laluque, Bordeaux (FR)

(21) Appl. No.: 14/016,009

(22) Filed: Aug. 30, 2013

(30) Foreign Application Priority Data
Aug. 31, 2012 (FR) 1202342

(51) Int. Cl. G09G 3/36

(52) U.S. Cl. CPC G09G 3/3611
USPC 345/6

(57) ABSTRACT

The general field of the invention is that of hybrid viewing devices comprising several screens of different nature. The device according to the invention comprises a stack comprising three superimposed viewing screens of the same dimensions and means for generating and processing images, the first viewing screen being a transparent emissive matrix screen, the second viewing screen being a matrix screen with controlled transparency, the third viewing screen being a transparent emissive matrix screen, the second viewing screen being disposed between the first viewing screen and the third viewing screen so as to be able to block all or part of the image displayed by the first viewing screen and/or the third viewing screen, the stack of three screens thus being arranged so as to be able to display an image on its first face and an image on its second face, the two images being able to be identical.

The field of the invention is that of transparent viewing screens. In certain technical fields, it is necessary to deploy viewing devices comprising transparent or semi-transparent screens which allow both the reading of the information displayed and the perception of the landscape situated behind the screen. In aeronautics, such screens can be used to provide useful information relating to piloting or navigation while enabling the crew to view the exterior landscape.

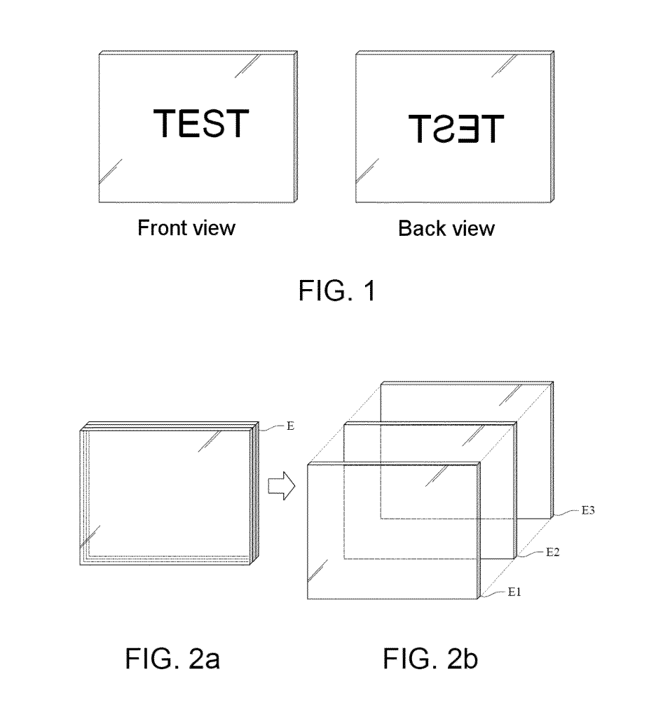

These screens are generally transparent “OLED” active matrix screens, OLED being the acronym standing for “Organic Light Emitting Diode”. These screens generally emit via both their faces. It is not currently possible to deploy such screens in aeronautical cockpits between the pilot and the copilot so as to provide information simultaneously to the pilot and to the copilot without creating an opaque barrier between the pilots. As seen in FIG. 1, if a transparent screen E is disposed between the pilot and the copilot, there is necessarily, if this screen is looked at from both sides, inversion of the display for one of the sides of the screen. Graphics and alphanumeric information are illegible from this side of the screen. The simple example of the word TEST, which is illegible back to front, has been taken in FIG. 1.

For some applications and notably for helicopters, such viewing screens are useful in so far as they make it possible to decrease the number of viewing screens disposed on the instrument panel, facing the crew members, thus increasing the perception of the exterior landscape situated in front of the crew. Indeed, with helicopters being able to fly at low altitude, it is essential that the crew members have the most unobstructed possible view of the exterior.

The viewing device according to the invention does not exhibit these drawbacks. It is composed of a stack of three flat screens, the first being a transparent emissive matrix screen, the second being a transparent blocking matrix screen, the third being a transparent emissive matrix screen. The first screen is intended for a first user, the third screen is intended for a second user. The blocking matrix screen being appropriately arranged, neither the first user, nor the second user perceives any illegible inverted display.

More precisely, the subject of the invention is a hybrid viewing device, characterized in that it comprises at least one stack comprising three superimposed viewing screens of the same dimensions and means for generating and processing images, the first viewing screen being a transparent emissive matrix screen constituting the first face of the stack, the second viewing screen being a matrix screen with controlled transparency, the third viewing screen being a transparent emissive matrix screen constituting the second face of the stack, the second viewing screen being disposed between the first viewing screen and the third viewing screen so as to be able to block all or part of the image displayed by the first viewing screen and/or the third viewing screen, the stack of three screens thus being arranged so as to be able to display an image on its first face and an image on its second face.

Advantageously, the device comprises means for generating a first image intended to be displayed on the first viewing screen and image processing means, the said processing means arranged so as:

to determine the symbols, the texts and the alphanumeric characters that are not left-right symmetric, present in the said first image;

to opacify at least the zones of the second viewing screen that are disposed at the location of the said symbols, of the said texts and of the said alphanumeric characters that are not symmetric of the first image;

to generate at least the said symbols, the said texts and the said alphanumeric characters that are not left-right symmetric in a second image intended to be displayed on the third viewing screen at the location of the said symbols, of the said texts and of the said alphanumeric characters that are not symmetric of the first image.

Advantageously, the opacified zones of the second viewing screen correspond strictly to the location of the said symbols, of the said texts and of the said alphanumeric characters that are not symmetric of the first image, the remainder of the second viewing screen being transparent.

Advantageously, the first viewing screen and the third viewing screen are matrix screens of OLED type and in that the second viewing screen is a liquid crystal screen with variable transmission or a polymer dispersed screen of PDLC type or a liquid crystal screen with variable transmission and reflection.

Advantageously, the first viewing screen and/or the third viewing screen comprise a touch-sensitive surface.

The invention also relates to an aircraft comprising a cockpit comprising two crew stations disposed side by side and a central pylon disposed between the said stations, characterized in that the central pylon comprises a hybrid viewing device as defined hereinabove, the said hybrid viewing device being disposed vertically in the central axis of the pylon in such a way that the first face of the facility is seen from the first station and the second face of the facility is seen from the second station.

The invention will be better understood and other advantages will become apparent on reading the description which follows given without limitation and by virtue of the appended figures among which:

FIG. 1 already commented on represents a screen according to the prior art with transparent “OLED” active matrix, seen from both sides of the screen;

FIGS. 2a and 2b represent the stack of the various screens of a viewing device according to the invention;

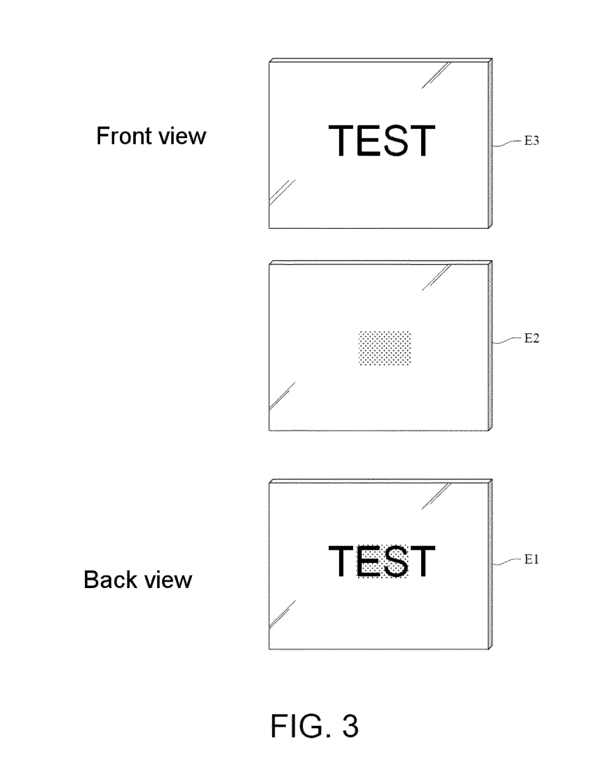

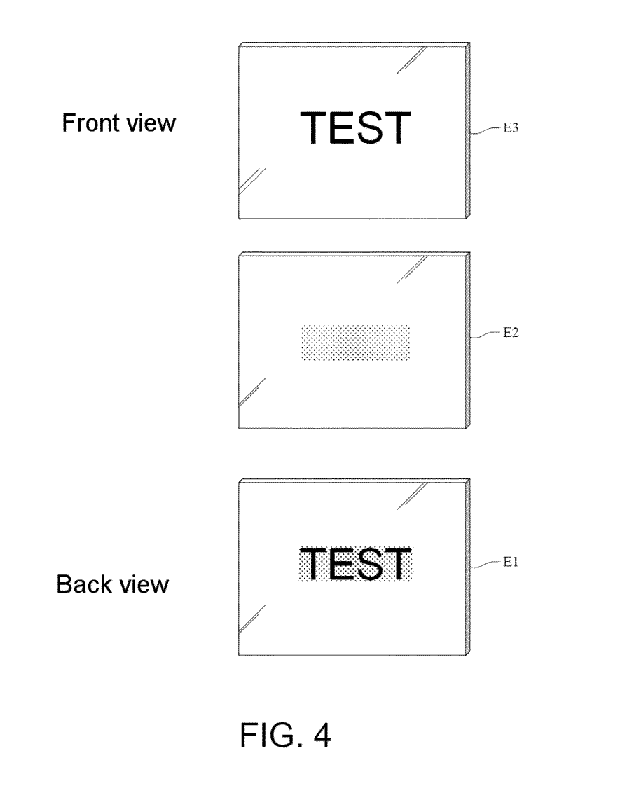

FIGS. 3 and 4 represent two variants of the display in a device according to the invention, seen from both sides of the screen.

The main objective of the hybrid viewing device according to the invention is to be able to display an image seen in a manner which is totally legible via these two opposite faces while preserving a certain transparency in such a way that a user can also see through the viewing device.

It comprises, as seen in the assembled view of FIG. 2a and the exploded view of FIG. 2b, a stack E comprising three superimposed viewing screens of the same dimensions and means for generating and processing images. The first viewing screen El is a transparent emissive matrix screen constituting the first face of the stack, the second viewing screen E2 is a matrix screen with controlled transparency, the third viewing screen E3 is a transparent emissive matrix screen constituting the second face of the stack, the second viewing screen being disposed between the first viewing screen and the third viewing screen so as to be able to block all or part of the image displayed by the first viewing screen and/or the third viewing screen, the stack of three screens thus being arranged so as to be able to display an image on its first face and an image on its second face.

The control of the luminous transmission of the second viewing screen can be obtained either by absorption of light, or by reflection. This second mode exhibits the advantage of increasing the luminance of the viewing screens.

By way of example, the first viewing screen E1 and the third viewing screen E3 are matrix screens of OLED type, the acronym signifying “Organic Light Emitting Diode”. By way of example, the second viewing screen E2 is a liquid crystal screen of LCD type, the acronym signifying “Liquid Crystal Display” whose transmission and/or reflection are variable. A screen of PDLC type, the acronym signifying “Polymer Dispersed Liquid Crystals”, can also be used for this function.

The first viewing screen and/or the third viewing screen can comprise a touch-sensitive surface. By way of first exemplary embodiment, the touch-sensitive surface can comprise optical emitters and receivers housed in the surround of the stack and arranged so as to determine the position of the users fingers when they are on the screen. It is also possible, by way of second exemplary embodiment, to implement capacitive or resistive technologies.

There exist various modes of use of the hybrid viewing device according to the invention. In a first mode of use, the second viewing screen E2 is totally blocking over the whole of its surface. In this case, the light emanating from the first viewing screen El may not reach the third viewing screen E3. The images displayed on the first screen or the third screen are therefore totally independent. They can be identical or different. In this mode, the users may not see through the viewing screens. This mode is beneficial when the display essentially comprises text or when the brightness is very significant. The best possible contrast of the information displayed is thus obtained.

In a second mode of use illustrated in FIGS. 3 and 4, the transparency of the emissive screens is favoured. The objective is to display an image which can be read in a manner that is legible by two users disposed on either side of the viewing device and each looking at a different face. Most of the images can be seen in transparency without any legibility problems, that is to say they support left-right inversion. Thus, by way of examples, a cartographic representation or a vertical sectional view of a flight plan support left-right inversion. Only the texts and the alphanumeric characters that are not symmetric and certain symbols become illegible through left-right inversion. The viewing device according to the invention makes it possible to solve this problem. It comprises image processing means arranged so as:

to determine the symbols, the texts and the alphanumeric characters that are not left-right symmetric, present in a first image;

to opacify at least the zones of the second viewing screen that are disposed at the location of the said symbols, of the said texts and of the said alpha-numeric characters that are not symmetric of the said first image;

to generate at least the said symbols, the said texts and the said alpha-numeric characters that are not left-right symmetric in a second image intended to be displayed on the third viewing screen at the location of the said symbols, of the said texts and of the said alphanumeric characters that are not symmetric of the first image.

This principle is illustrated in a simple manner in FIG. 3. It is sought to render legible the word “TEST” emitted by the first screen from both sides of the stack. This word comprises two dissymmetric letters which are the E and the S and two perfectly symmetric and symmetrically disposed letters which are the two Ts. At the location of the two letters E and S, the second screen is opacified in such a way that these letters are not perceived from the side of the third screen. This corresponds to the hatched zone in FIG. 3. At their location, the letters E and S are generated the correct way round on the third viewing screen. An observer placed on the side of the third screen sees the word “TEST” written the correct way round, the two Ts emanate from the first screen and the E and the S emanate from the third screen.

Of course, it is possible to opacify the entire location corresponding to the word so as to obtain an illumination and a contrast that are perfectly homogeneous over the whole of the word, even if this word comprises symmetric parts. This principle is illustrated in a simple manner in FIG. 4. It is sought to render legible the word “TEST” emitted by the first screen from both sides of the stack. At the location of the four letters T, E, S and T, the second screen is opacified in such a way that these letters are not perceived from the side of the third screen. This corresponds to the hatched zone in FIG. 4. At their location, the letters T, E, S and T are generated the correct way round on the third viewing screen. An observer placed on the side of the third screen sees the word “TEST” written the correct way round on an opaque background. The advantage of this solution is that the word is perfectly uniform.

In the general case, words do not possess any symmetrically disposed letters and the second screen is opacified at the location of the entire word even if certain letters of which the word is composed are perfectly symmetric. Thus, the three letters of the French word “OUI”, although all individually symmetric, give, seen back to front, the word “IUO” which has to be totally inverted.

The main benefit of this provision is that the remainder of the stack remains perfectly transparent.

This type of hybrid viewing device according to the invention is well suited to helicopters whose cockpit comprises two crew stations disposed side by side and a central pylon disposed between the said stations. The central pylon then comprises a hybrid viewing device according to the invention disposed vertically in the central axis of the pylon in such a way that the first face of the facility is seen from the first station and the second face of the facility is seen from the second station.

1. Hybrid viewing device, wherein it comprises at least one stack comprising three superimposed viewing screens of the same dimensions and means for generating and processing images, the first viewing screen being a transparent emissive matrix screen constituting the first face of the stack, the second viewing screen being a matrix screen with controlled transparency, the third viewing screen being a transparent emissive matrix screen constituting the second face of the stack, the second viewing screen being disposed between the first viewing screen and the third viewing screen so as to be able to block all or part of the image displayed by the first viewing screen and/or the third viewing screen, the stack of three screens thus being arranged so as to be able to display an image on its first face and an image on its second face.

2. Hybrid viewing device according to claim 1, wherein the device comprises means for generating a first image intended to be displayed on the first viewing screen and image processing means, the said processing means arranged so as:
to determine the symbols, the texts and the alphanumeric characters that are not left-right symmetric, present in the said first image;
to opacify at least the zones of the second viewing screen that are disposed at the location of the said symbols, of the said texts and of the said alphanumeric characters that are not symmetric of the first image;
to generate at least the said symbols, the said texts and the said alphanumeric characters that are not left-right symmetric in a second image intended to be displayed on the third viewing screen at the location of the said symbols, of the said texts or of the said alphanumeric characters that are not symmetric of the first image.

3. Hybrid viewing device according to claim 2, wherein the opacified zones of the second viewing screen correspond strictly to the location of the said symbols, of the said texts or of the said alphanumeric characters that are not symmetric of the first image, the remainder of the second viewing screen being transparent.

4. Hybrid viewing device according to claim 1, wherein the first viewing screen and the third viewing screen are matrix screens of OLED type and in that the second viewing screen is a liquid crystal screen with variable transmission or a polymer dispersed liquid crystal screen or a liquid crystal screen with variable transmission and reflection.

5. Hybrid viewing device according to claim 1, wherein the first viewing screen and/or the third viewing screen comprises a touch-sensitive surface.

6. Aircraft comprising a cockpit comprising two crew stations disposed side by side and a central pylon disposed between the said stations, wherein the central pylon comprises a hybrid viewing device comprising at least one stack comprising three superimposed viewing screens of the same dimensions and means for generating and processing images, the first viewing screen being a transparent emissive matrix screen constituting the first face of the stack, the second viewing screen being a matrix screen with controlled transparency, the third viewing screen being a transparent emissive matrix screen constituting the second face of the stack, the second viewing screen being disposed between the first viewing screen and the third viewing screen so as to be able to block all or part of the image displayed by the first viewing screen and/or the third viewing screen, the stack of three screens thus being arranged so as to be able to display an image on its first face and an image on its second face, the said hybrid viewing device being disposed vertically in the central axis of the pylon in such a way that the first face of the facility is seen from the first station and the second face of the facility is seen from the second station.

7. Hybrid viewing device according to claim 2, wherein the first viewing screen and the third viewing screen are matrix screens of OLED type and in that the second viewing screen is a liquid crystal screen with variable transmission or a polymer dispersed liquid crystal screen or a liquid crystal screen with variable transmission and reflection.

8. Hybrid viewing device according to claim 2, wherein the first viewing screen and/or the third viewing screen comprises a touch-sensitive surface.

9. The aircraft of claim 6, wherein the hybrid viewing device comprises means for generating a first image intended to be displayed on the first viewing screen and image processing means, the said processing means arranged so as:
to determine the symbols, the texts and the alphanumeric characters that are not left-right symmetric, present in the said first image;
to opacify at least the zones of the second viewing screen that are disposed at the location of the said symbols, of the said texts and of the said alphanumeric characters that are not symmetric of the first image;
to generate at least the said symbols, the said texts and the said alphanumeric characters that are not left-right symmetric in a second image intended to be displayed on the third viewing screen at the location of the said symbols, of the said texts or of the said alphanumeric characters that are not symmetric of the first image.

10. The aircraft of claim 6, wherein the first viewing screen and the third viewing screen are matrix screens of OLED type and in that the second viewing screen is a liquid crystal screen with variable transmission or a polymer dispersed liquid crystal screen or a liquid crystal screen with variable transmission and reflection.
